(19) United States
(12) Patent Application Publication
(10) Pub. No.: US 2019/0006254 A1
(43) Pub. Date: Jan. 3, 2019

(54) MICROELECTRONIC PACKAGE CONSTRUCTION ENABLED THROUGH CERAMIC INSULATOR STRENGTHENING AND DESIGN

(71) Applicant: Kyocera International, Inc., San Diego, CA (US)

(72) Inventors: Mark EBLEN, Temecula, CA (US); Franklin KIM, San Diego, CA (US); Paul GARLAND, Poway, CA (US); Shinichi HIRA, San Diego, CA (US)

(21) Appl. No.: 16/021,454

(22) Filed: Jun. 28, 2018

Related U.S. Application Data
(60) Provisional application No. 62/527,315, filed on Jun. 30, 2017.

(51) Int. Cl. H01L 23/29; H01L 23/367; H01L 23/373; H01L 23/40

(52) U.S. Cl. CPC H01L 23/29; H01L 23/40; H01L 23/3731; H01L 23/3677

(57) ABSTRACT

A semiconductor packaging structure is disclosed. The semiconductor packaging structure includes a heat spreader, a set of at least two leads, and a ceramic insulator. The heat spreader has a thermal conductivity greater than 300 W/m*K. The ceramic insulator has a mean flexural strength that is greater than 500 MPa and so better able to withstand the thermal expansion mismatch between it and the heat spreader. The heat spreader, the set of at least two leads, and the ceramic insulator may also be part of a semiconductor package along with at least one semiconductor device, a wire bond, and a ceramic lid.

### RELATED APPLICATIONS

The application claims the benefit of priority of U.S. Provisional Patent Application Ser. No. 62/527,315, entitled “MICROELECTRONIC PACKAGE CONSTRUCTION ENABLED THROUGH CERAMIC INSULATOR STRENGTHENING AND DESIGN”, filed on Jun. 30, 2017, and incorporated by reference in its entirety, herein.

### BACKGROUND

Semiconductor devices can be used as amplifiers for high power microwave transmissions. These devices are part of base stations and mobile systems of wireless networks used for telecommunications and metro communications. For example, a semiconductor device may be a Gallium nitride (GaN) transistor or a GaN Microwave Monolithic Integrated Circuit (MMIC) used as a high power amplifier. Recently, device power is increasing, allowing higher performance even with a small size die. As such, more cost effective solutions with better thermal dissipation are needed as these amplifiers increase in number and replace current amplifiers.

Heat spreader material for devices, for example high power amplifiers, must be chosen to have high thermal dissipation. The heat spreader material should also be suitable for volume manufacturing. For the packaging of semiconductor devices, copper laminate heat spreader materials in the ratio 1-4-1 with a molybdenum/copper (MoCu) dispersed composite core layer are frequently used in the fabrication of the heat spreaders. However, these heat spreader materials do not have enough thermal dissipation to manage the heat generated by high power semiconductor devices. Other materials used in heat spreaders, for example, special composite materials with diamond or graphite fibers, have been developed to manage good thermal conductivity. However, these special composite materials, especially those with diamond, tend to be very expensive. In addition, these materials present difficulties in the manufacturing process, such as poor yield during plating and brazing, which in turn affects their suitability for volume manufacturing.

A logical low cost choice for a heat spreader is copper. However, copper has a high thermal expansion, which does not match well to the coefficient of thermal expansion of a ceramic frame. The coefficient of thermal expansion difference between copper materials and ceramic frames is too great to manage the extremes of an accelerated life reliability temperature cycling test, where free standing or bolted down package experiences moderate extremes in temperature of −65 C to 150 C for hundreds of cycles. If reliability tests are not managed adequately, then the reliability of the semiconductor devices and the semiconductor packages will be lower, and failure of the semiconductor devices and semiconductor packages may occur. Thus, there is a need for improved semiconductor packages.

### SUMMARY

A semiconductor packaging structure includes a higher dissipation heat spreader approaching the thermal conductivity of copper and a ceramic insulator that has a high mechanical strength. The high mechanical strength of the ceramic insulator enables it to withstand the thermal-mechanical stress produced from a mismatch of thermal properties between the ceramic insulator and the metal of the heat spreader, and to withstand subsequent industry mandated accelerated life thermal testing. The high thermal dissipation heat spreader, the ceramic insulator and the leads are all chosen to be cost effective.

### BRIEF DESCRIPTION OF THE DRAWINGS

It is to be understood that the drawings are solely for a purpose of illustration and do not define the limits of the invention(s). Furthermore, the components in the figures are not necessarily to scale. In the figures, like reference numerals designate corresponding parts throughout the different views.

FIG. 1 is an exploded view of a semiconductor packaging structure, for example, a semiconductor radio frequency (RF) telecommunications package.

FIG. 2 is a cross section of a semiconductor packaging structure with a ceramic lid.

FIG. 3 is a top view of a structure of a semiconductor package without a ceramic lid.

FIG. 4 is a bottom view of a ceramic frame including an inside corner radius and refractory metallization for a semiconductor package.

FIG. 5 is a view of a microstructure of a ceramic used within a ceramic frame of a semiconductor package.

FIG. 6 is a view of an inside corner radius of a ceramic frame within a semiconductor package that shows the first principal stress distribution throughout the ceramic frame during a temperature cycling test.

FIG. 7 is a view of a semiconductor packaging structure alternative to the semiconductor packaging structure depicted in FIG. 1.

### DETAILED DESCRIPTION

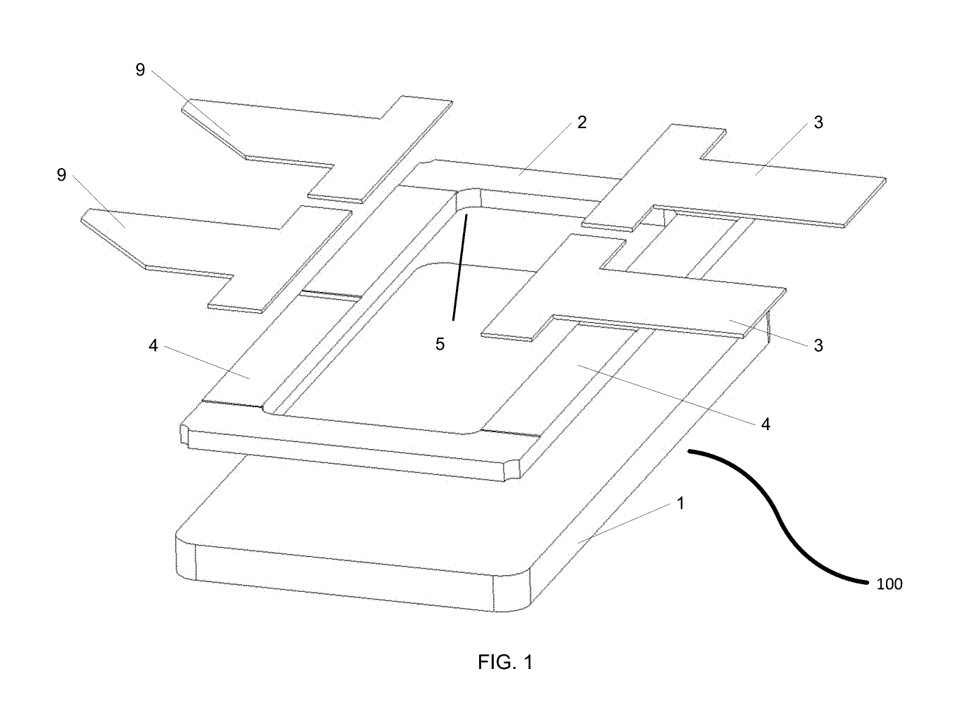

FIG. 1 depicts a structure of a semiconductor package 100. The semiconductor package 100 includes a heat spreader 1. The heat spreader 1 may be constructed of copper or other copper laminate based material as discussed below. Heat spreader 1 has a thermal conductivity that is greater than 300 W/m*K. It is preferable for the thermal conductivity of heat spreader 1 to be between 325 and 400 W/m*K when used in semiconductor package depicted in FIG. 1 with the maximum thermal conductivity for the heat spreader being equal to that of copper.

A ceramic insulator 2, also referred to herein as a ceramic frame, is fitted above the heat spreader 1. The semiconductor package 100 also includes at least one lead 3 and one drain lead 9. Each lead may be connected to a semiconductor device or a component thru a small diameter wirebond. Lead 3 and drain lead 9 are electrically isolated from heat spreader 1 by a ceramic insulator or ceramic frame 2 with a metallization pattern 4. The leads are attached on the ceramic insulator 2, and the ceramic insulator 2 is attached on the heat spreader 1 by using a braze, a solder, or a glue. The semiconductor package has a plating for device attach, and wire bonding for component assembly.

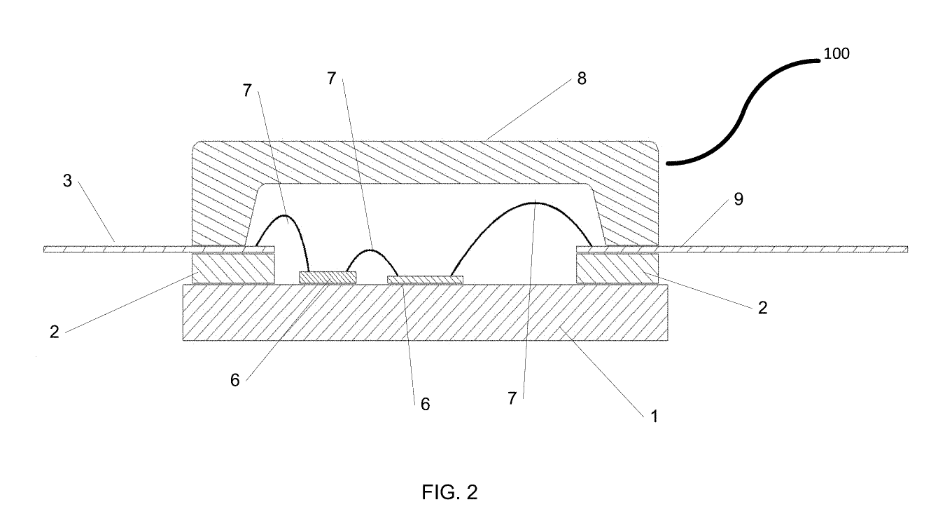

FIG. 2 depicts a cross section of a semiconductor or microelectronic package 100. A semiconductor package 100 includes semiconductor devices 6. Wire bonds 7 provide connections between the semiconductor devices 6, leads 3, and drain leads 9. FIG. 2 illustrates a ceramic lid or cap 8 which provides a hermetic seal for the semiconductor package. Ceramic lid or cap 8 is attached by epoxy or glue to the ceramic insulator 2, lead 3, and drain lead 9.

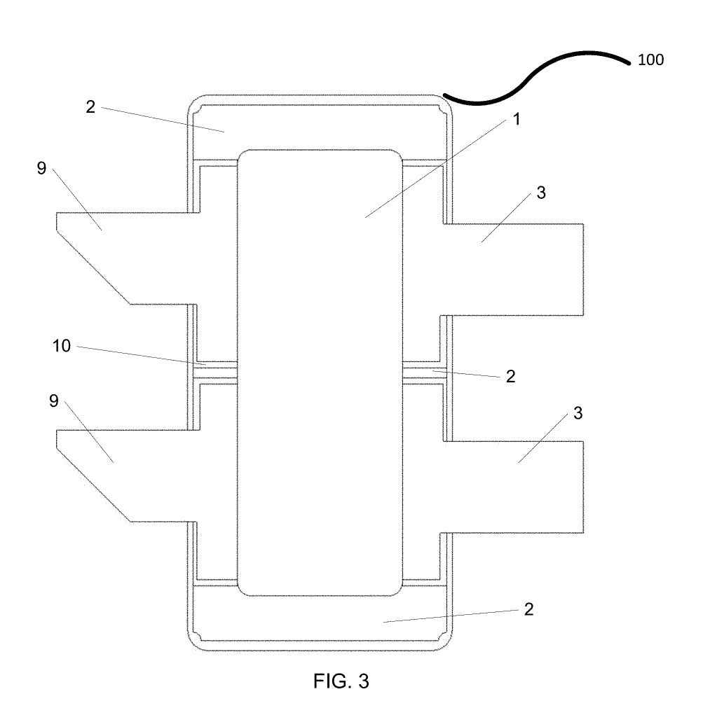

FIG. 3 depicts a top view of a semiconductor package 100. A ceramic insulator 2 is positioned on top of heat spreader 1. Braze 10 is applied to metallization pattern 4 (see FIG. 1) in order to attached leads 3 and drain leads 9 to ceramic insulator 2. Braze 10 may include braze fillets; that is, small amounts of braze material that protrude beyond a braze joint.

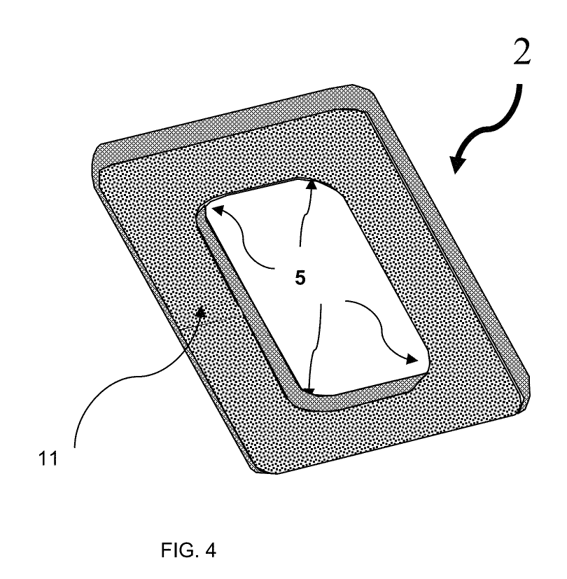

FIG. 4 is a bottom view of ceramic insulator 2, which includes an inside corner radius 5 and metallization 11. The inside corners of ceramic frame 2 distributes the peak stress on the ceramic frame caused by the difference between the coefficient of thermal expansion (CTE) of the heat spreader 1 and the ceramic frame 2. Braze is applied between the heat spreader 1 and the metallization area 11 of ceramic insulator 2 in order to attach the ceramic insulator to the heat spreader.

An example ceramic insulator 2 is an alumina material with high reliability and good adhesive metallization, and is capable of being manufactured in volume. In order to match the thermal expansion properties of high thermal dissipation heat spreader 1, the ceramic insulator 2 has increased flexural strength. The mean flexural strength of the ceramic insulator is preferably above 500 MPa, and is even more preferably between 600 and 650 MPa when tested in a three point configuration. The ceramic insulator 2 may also have at least one of the following properties: a thermal conductivity between 14 to 21 W/m*K; a Young's modulus between 275 and 325 GPa; and a coefficient of thermal expansion (CTE) between 7 and 7.5 ppm/K between 300° C. and 400° C.

During an accelerated life environmental test, the semiconductor package 100 will have to withstand a thermal cycling test. The temperature range that a semiconductor device assembly will be exposed to for checking reliability via thermal cycling is, for example, from −65° C. to +150° C. for a 500 cycle test. An example ceramic insulator 2 that has a flexural strength between 600 and 650 MPa, may be better able to withstand a thermal expansion mismatch between it and heat spreader 1. More specifically, a ceramic insulator 2 may be better able to withstand the stress caused by heat spreader 1 having a greater CTE than it has. The flexural strength of ceramic insulator 2 may be increased by reducing the grain size during sintering, by changing its material formation, and/or by changing the nature of the binding glass phase in the material.

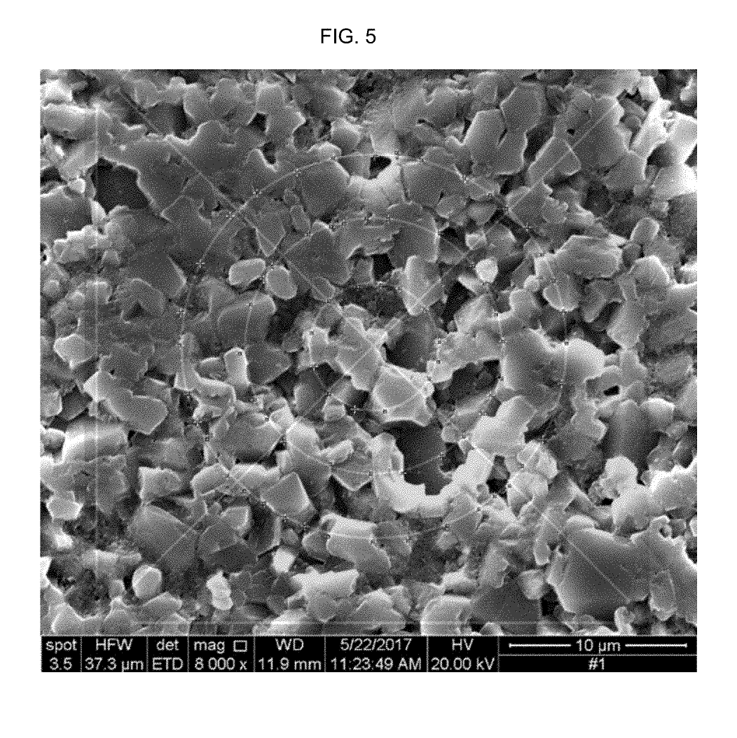

FIG. 5 is a view of a ceramic that may be used in a ceramic frame or insulator 2. While there are different methods of increasing the flexural strength of the ceramic used within ceramic insulator 2, the primary method of doing so is by reducing its grain size. The ceramics used within semiconductor packages are polycrystalline ceramics, and their grain structure can be viewed with the use of either an optical or scanning electron microscope. The average grain size of the ceramic body shown in FIG. 5 is preferably less than 3 microns, and even more preferably is between 1.5 and 2.5 microns. Flexural strength is inversely related to grain size; therefore, a smaller grain size increases the flexural strength of the polycrystalline ceramic. More specifically strength scales inversely with grain size according to the Hall-Petch equation, σ_{F}=σₒ+Kd^{-0.5}, where d is the grain size, σ_{F} is the fracture stress, σ₀ is a constant representing the starting stress required for crystal slip, and K is a material constant related to strengthening.

Referring to FIGS. 1, 3 and 4, the example ceramic insulator 2, also referred to as a ceramic window frame, is rectangular or square in shape with an open space, i.e. a cut-out section or window in a middle portion of the ceramic frame. As shown in FIG. 2, devices 6 are attached on top of heat spreader 1 and within the window of ceramic insulator 2. Ceramic insulator 2 has rounded corners on its inside edges. Ceramic insulator outside corner geometry, as shown in FIG. 1, may vary according to manufacturing requirements, for example, to improve snapping a sheet of ceramic insulators for low volume cost.

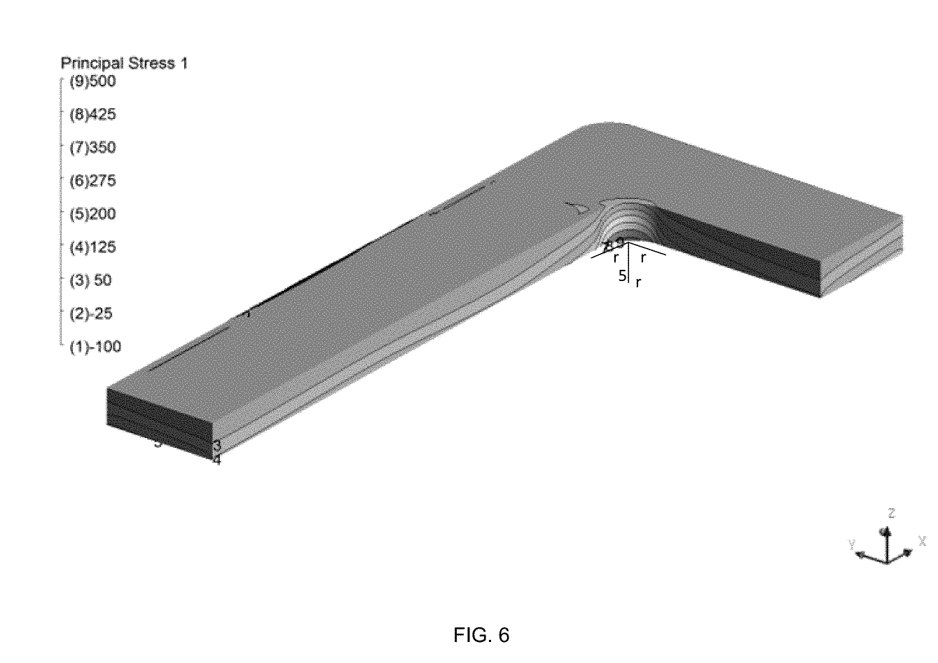

FIG. 6 is a close up view of an inside corner radius 5 of an inside corner of ceramic insulator 2. The inside corner radius 5 for an example ceramic insulator 2 is the same value r for all four corners. Radius 5 may be between 20 to 50 mils, with 20 mils being the industry preferred standard. However, it may be preferable for radius 5 to be less than 18 mils, and even more preferable for it to be between 15 and 17 mils to increase the total area of the window of the ceramic insulator 2. That is, a smaller radius provides a greater area in which to place devices inside of ceramic insulator 2. While there are benefits to having a smaller inside corner radius, a smaller inside corner radius also makes the ceramic insulator or frame more prone to cracking on the inside corners when the ceramic insulator is under thermal stress. If the ceramic insulator has a flexural strength in the range of 600 to 650 MPa, and an inside corner radius between 15 and 17 mils, then the reliability of the semiconductor package is increased while also enabling more flexible design. During an accelerated life reliability temperature cycling test, the stress on ceramic insulator 5 will vary with location with the greatest stress found on the bottom of each inside corner of the ceramic insulator 5.

The ceramic insulator 2 may be comprised of ceramic material including, but not limited to, alumina, aluminum nitride, zirconia, forsterite, and steatite. The metallization 11 may be comprised of a high temperature (>1000° C.) fired metallization including, but not limited to, Tungsten (W), Molybdenum (Mo), and Moly-Manganese (MoMn). The ceramic cap 8 may be comprised of ceramic material including, but not limited to, alumina, aluminum nitride, zirconia, forsterite, and steatite.

As shown in FIG. 1 and FIG. 3, semiconductor package 100 will typically have a total of four leads, two of which will be drain leads. The leads 3 and drain leads 9 may include a Fe—Ni alloy, Fe—Ni—Co alloy, Cu—Ni alloy, Cu, Ni, and/or other metals with equivalent electrical performance. A configuration using eight leads within semiconductor package 100 is also possible with an additional lead at each corner of the ceramic insulator (not shown). In one example, leads 3 will be disposed along one length of the ceramic insulator and drain leads 9 will be disposed on an opposite length. Example drain leads 9, as shown in FIGS. 1 and 3 are chamfered while lead 3 are not chamfered. As described above, braze 10 is applied to metallization pattern 4 in order to attached leads 3 and drain leads 9 to ceramic insulator 2. Each lead is attached via braze to a corresponding metallization pattern 4 on the ceramic insulator 2. As shown in FIGS. 1 and 3, each combination of braze 10 and metallization pattern 4 is surrounded on all sides by ceramic insulator 2 in order to electrically isolate the leads from one another.

The heat spreader 1, the ceramic frame 2, the lead 3, and drain lead 9 are attached by brazing, soldering or adhesive material including, but not limited to AgCu, AuGe, AuSi, AuSn, any other solders or glues.

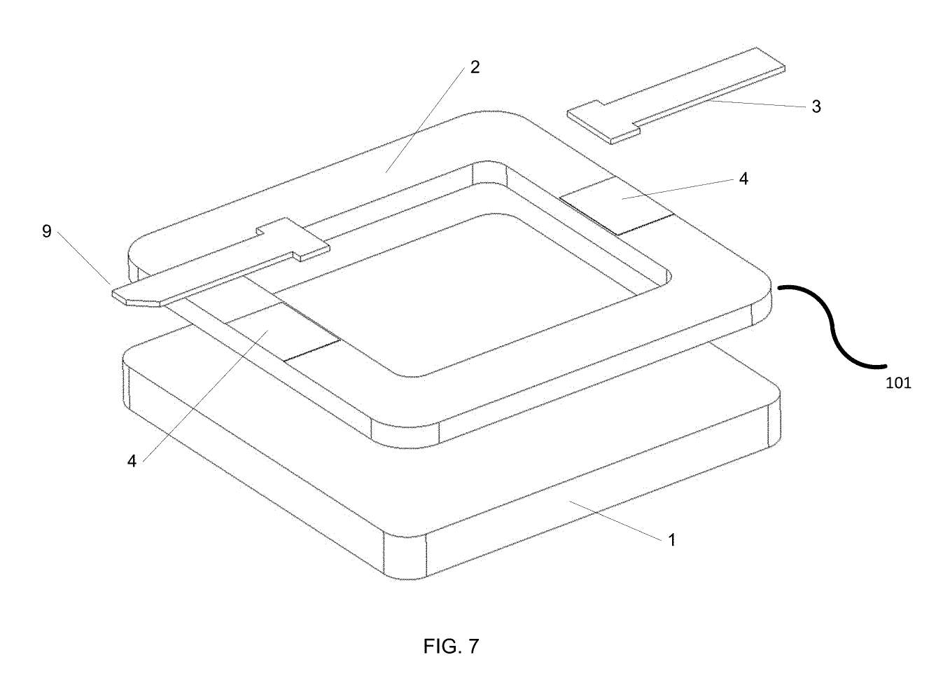

As shown in FIG. 7, an alternative semiconductor packaging structure is also possible. Semiconductor package 101 is smaller than semiconductor package 100, and therefore is limited to having two leads, one of which will be a drain lead. Similar to larger semiconductor package 100, semiconductor package 101 also has a heat spreader 1, ceramic frame 2, and metallization pattern 4. In semiconductor package 101, the heat spreader may have a thermal conductivity above 400 W/m*K.

Example semiconductor packages as described herein, have electrolytic plating comprising a nickel plating, a palladium plating and a gold plating on the heat spreader, the leads, and the metallization. The palladium plating including, but not limited to, pure Palladium (Pd), Palladium Cobalt alloy (Pd Co), Palladium Nickel alloy (Pa Ni), and Palladium Indium alloy (Pd In). The palladium plating provides a lower plating cost due to a thinner gold thickness and having a function as a diffusion barrier between the nickel plating and gold plating.

What is claimed is:

1. A microelectronic package comprising:
a heat spreader, wherein the heat spreader has a thermal conductivity above 300 W/m*K;
a ceramic insulator attached to the heat spreader, wherein the ceramic insulator has a mean flexural strength above 500 MPa; and
a set of at least two leads, wherein the set of leads is attached to the ceramic insulator.

2. The microelectronic package of claim 1, wherein the ceramic insulator comprises a cut-out section having an inside corner, the inside corner having a radius of less than 18 mils.

3. The microelectronic package of claim 1, wherein the ceramic insulator comprises a cut-out section having an inside corner, the inside corner having a radius between 20 and 50 mils.

4. The microelectronic package of claim 2, the microelectronic package further comprising:
at least one semiconductor device, the at least one semiconductor device attached on top of the heat spreader and within the cut-out section of the ceramic insulator.

5. The microelectronic package of claim 2, further comprising a first braze that attaches the ceramic insulator to the heat spreader.

6. The microelectronic package of claim 5, further comprising:
a metallization pattern on top of the ceramic insulator.

7. The microelectronic package of claim 6, wherein the metallization pattern comprises tungsten.

8. The microelectronic package of claim 6, further comprising a second braze, over the metallization pattern, wherein the second braze attaches the set of leads to the ceramic insulator, further wherein the first braze and the second braze are comprised of the same metal.

9. The microelectronic package of claim 7, wherein the ceramic insulator comprises a ceramic material having an average grain size of less than three microns.

10. The microelectronic package of claim 6, wherein the metallization pattern comprises molybdenum.
